(19) United States
(12) Patent Application Publication
(10) Pub. No.: US 2025/0087594 A1
(43) Pub. Date: Mar. 13, 2025

(54) LIGHT-EMITTING DIODE CHIP AND LIGHT-EMITTING DEVICE

(71) Applicant: Xiamen San'an Optoelectronics Co., Ltd., Fujian (CN)

(72) Inventors: Jenlung YANG, Fujian (CN); Ping ZHANG, Fujian (CN); Yawen LIN, Fujian (CN); Shiwang HUANG, Fujian (CN); Xianjie ZHANG, Fujian (CN); Chungying CHANG, Fujian (CN)

(73) Assignee: Xiamen San'an Optoelectronics Co., Ltd., Fujian (CN)

(21) Appl. No.: 18/820,246

(22) Filed: Aug. 29, 2024

(30) Foreign Application Priority Data
Sep. 8, 2023 (CN) 202311156819.2

(51) Int. Cl. H01L 23/544; H01L 33/24; H01L 33/44

(52) U.S. Cl. CPC H01L 23/544; H10H 20/821; H10H 20/84; H01L 2223/5446

(57) ABSTRACT

The disclosure relates to a light-emitting diode, which includes a semiconductor stacked structure, a channel, a first electrode, and a second electrode. The channel surrounds the semiconductor stacked structure. When viewed from above the light-emitting diode toward the semiconductor stacked structure, the semiconductor stacked structure has at least one chamfered portion located in the channel, and a range of a radius of curvature of the chamfered portion is from 5 to 50 microns. Through the optimization of the morphology of the LED chip epitaxial layer edges in the intersection region of the channel, the damage to the epitaxial layer caused by laser energy during stealth dicing is reduced, thereby achieving the objective of enhancing chip reliability.

### CROSS-REFERENCE TO RELATED APPLICATION

This application claims the priority benefit of China application serial no. 202311156819.2, filed on Sep. 8, 2023. The entirety of the above-mentioned patent application is hereby incorporated by reference herein and made a part of this specification.

### BACKGROUND

### Technical Field

The disclosure relates to the technical field of semiconductor devices, and in particular relates to a light-emitting diode chip and a light-emitting device.

### Description of Related Art

Light-emitting diodes (LEDs) possess numerous advantageous characteristics, including high efficiency, high service life, small sizes, and low power consumption. Consequently, LEDs have been widely implemented in indoor and outdoor white light lighting, screen display, backlight, and other fields.

The current manufacturing process of LED chips mainly involves growing epitaxial materials on a substrate, then etching the wafer to produce corresponding LED pattern particles. The substrate is then ground and thinned, and then laser stealth dicing is adopted to cut the LED wafer into single LED chips for separation. During the laser stealth dicing process, the laser performs cross-scanning along the horizontal channels and vertical channels in sequence. Therefore, there are two stealth dicing energy impacts at the corners of the epitaxial layer of the LED chip at the channel intersection region, which may easily damage the chip structure and cause electrical abnormalities. Therefore, the reliability of elements are affected, leading to a decrease in LED chip yield, thereby increasing manufacturing costs. Secondly, when the width of the channel is designed to be narrow, the stealth dicing window in the channel intersection region will be too small, which easily damages the epitaxial layer and significantly reduces the product yield. Therefore, there is a need to provide an improved technical solution to address the deficiencies in the above-mentioned prior art.

### SUMMARY

In view of the above defects and deficiencies in the prior art, a light-emitting diode chip and a light-emitting device are provided in the disclosure. Through the optimization of the morphology of the LED chip epitaxial layer corners in the intersection region of the channel, the damage to the epitaxial layer caused by laser energy during stealth dicing is reduced, thereby achieving the objective of enhancing chip reliability.

According to an embodiment of the disclosure, a light-emitting diode is provided, comprising: a semiconductor stacked structure, comprising a first semiconductor layer, a light-emitting layer, and a second semiconductor layer, the light-emitting layer being located between the first semiconductor layer and the second semiconductor layer; a channel, surrounding the semiconductor stacked structure; a first electrode, located on the first semiconductor layer; a second electrode, located on the second semiconductor layer; wherein when viewed from above the light-emitting diode toward the semiconductor stacked structure, the semiconductor stacked structure has at least one chamfered portion located on the channel, and a range of a radius of curvature of the at least one chamfered portion is from 5 microns to 50 microns.

According to another aspect of the disclosure, a light-emitting diode is provided, comprising: a semiconductor stacked structure, comprising a first semiconductor layer, a light-emitting layer, and a second semiconductor layer, the light-emitting layer being located between the first semiconductor layer and the second semiconductor layer; a first electrode, located on the first semiconductor layer; a second electrode, located on the second semiconductor layer; wherein when viewed from above the light-emitting diode toward the semiconductor stacked structure, the semiconductor stacked structure has at least one first type chamfered portion and at least one second type chamfered portion, a distance between the at least one first type chamfered portion and the first electrode is less than a distance between the at least one second type chamfered portion and the first electrode, a radius of curvature of the at least one first type chamfered portion is less than a radius of curvature of the at least one second type chamfered portion.

According to another aspect of the disclosure, a light-emitting diode is provided, comprising: a semiconductor stacked structure, comprising a first semiconductor layer, a light-emitting layer, and a second semiconductor layer, the light-emitting layer being located between the first semiconductor layer and the second semiconductor layer; a first electrode, located on the first semiconductor layer; a second electrode, located on the second semiconductor layer; wherein the semiconductor stacked structure has a shortest side, a size of the shortest side is y microns, when viewed from above the light-emitting diode toward the semiconductor stacked structure, the semiconductor stacked structure has at least one chamfered portion, a range of a radius of curvature of the at least one chamfered portion is from 5 microns to y/3 microns.

According to another aspect of the disclosure, a light-emitting device is provided, which adopts the light-emitting diode chip provided in any of the above embodiments.

As mentioned above, the light-emitting diode chip and the light-emitting device of the present application have the following beneficial effects.

Firstly, the LED chip epitaxial layer corner positions of the channel intersection region is optimized through methods such as expanding the radius of curvature of the chamfered portion of the LED chip epitaxial layer located at the channel intersection position, or disposing chamfered portions with different radius of curvature on the epitaxial layer at different positions of the chip. By expanding the radius of curvature of the chamfered portion, which is equivalent to expanding the stealth dicing window in the channel intersection region, damage to the epitaxial layer caused by laser energy during stealth dicing may be effectively avoided, preventing electrical abnormalities caused by damage to the chip structure. Therefore, the purpose of enhancing chip reliability is achieved, thereby greatly improving product yield and reducing manufacturing costs. While expanding the radius of curvature of the chamfered portion, the width of the channels may also be correspondingly reduced, thereby increasing the effective light-emitting area of the LED chip and improving the luminous efficiency of the LED chip. Furthermore, by disposing chamfered portions with different radius of curvature on the epitaxial layer at different positions of the chip, the reliability of the chip may be improved while ensuring a larger effective light-emitting area of the LED chip, further improving the luminous efficiency of the LED chip.

### BRIEF DESCRIPTION OF THE DRAWINGS

FIG. 1 is a schematic diagram of a channel.

FIG. 2 is a partially enlarged schematic diagram of position P in FIG. 1.

FIG. 3 is a top view of a structural schematic diagram of the light-emitting diode chip provided in Embodiment 1 of the disclosure.

FIG. 4 is a partially enlarged schematic diagram of region A in FIG. 3.

FIG. 5 is a cross-sectional structural schematic diagram along the F-F1 direction in FIG. 3.

FIG. 6 is a top view of a structural schematic diagram of the light-emitting diode chip provided in Embodiment 2 of the disclosure.

FIG. 7 is a partial enlarged comparison schematic diagram of region A and region B in FIG. 6.

FIG. 8 is a top view of a structural schematic diagram of the light-emitting diode chip provided in Embodiment 3 of the disclosure.

FIG. 9 is a top view of a structural schematic diagram of another light-emitting diode chip provided in Embodiment 3 of the disclosure.

FIG. 10 is a top view of a structural schematic diagram of the light-emitting diode chip provided in Embodiment 4 of the disclosure.

FIG. 11 is a top view of a structural schematic diagram of another light-emitting diode chip provided in Embodiment 4 of the disclosure.

FIG. 12 is a top view of a structural schematic diagram of the light-emitting diode chip provided in Embodiment 5 of the disclosure.

FIG. 13 is a top view of a structural schematic diagram of another light-emitting diode chip provided in Embodiment 5 of the disclosure.

FIG. 14 is a top view of a structural schematic diagram of the light-emitting diode chip provided in Embodiment 6 of the disclosure.

FIG. 15 is a cross-sectional structural schematic diagram along the F-F1 direction in FIG. 14.

### DETAILED DESCRIPTION OF DISCLOSED EMBODIMENTS

In view of the above defects and deficiencies in the prior art, a light-emitting diode chip and a light-emitting device are provided in the disclosure. Through optimizing the disposition of the LED chip epitaxial layer corner positions in the channel intersection region, the reliability of the light-emitting diode chip is enhanced. It should be noted that the channel in the disclosure refers to the region between the edge of the semiconductor stacked structure and the edge of the light-emitting diode. That is, the width of the channel refers to the distance between the edge of the semiconductor stacked structure and the edge of the light-emitting diode.

According to an embodiment of the disclosure, a light-emitting diode is provided, comprising: a semiconductor stacked structure, comprising a first semiconductor layer, a light-emitting layer, and a second semiconductor layer, the light-emitting layer being located between the first semiconductor layer and the second semiconductor layer; a channel, surrounding the semiconductor stacked structure; a first electrode, located on the first semiconductor layer; a second electrode, located on the second semiconductor layer; wherein when viewed from above the light-emitting diode toward the semiconductor stacked structure, the semiconductor stacked structure has at least one chamfered portion located on the channel, and a range of a radius of curvature of the at least one chamfered portion is from 5 microns to 50 microns.

According to another aspect of the disclosure, a light-emitting diode is provided, comprising: a semiconductor stacked structure, comprising a first semiconductor layer, a light-emitting layer, and a second semiconductor layer, the light-emitting layer being located between the first semiconductor layer and the second semiconductor layer; a first electrode, located on the first semiconductor layer; a second electrode, located on the second semiconductor layer; wherein when viewed from above the light-emitting diode toward the semiconductor stacked structure, the semiconductor stacked structure has at least one first type chamfered portion and at least one second type chamfered portion, a distance between the at least one first type chamfered portion and the first electrode is less than a distance between the at least one second type chamfered portion and the first electrode, a radius of curvature of the at least one first type chamfered portion is less than a radius of curvature of the at least one second type chamfered portion.

According to another aspect of the disclosure, a light-emitting diode is provided, comprising: a semiconductor stacked structure, comprising a first semiconductor layer, a light-emitting layer, and a second semiconductor layer, the light-emitting layer being located between the first semiconductor layer and the second semiconductor layer; a first electrode, located on the first semiconductor layer; a second electrode, located on the second semiconductor layer; wherein the semiconductor stacked structure has a shortest side, a size of the shortest side is y microns, when viewed from above the light-emitting diode toward the semiconductor stacked structure, the semiconductor stacked structure has at least one chamfered portion, a range of a radius of curvature of the at least one chamfered portion is from 5 microns to y/3 microns.

The range of the radius of curvature of the chamfered portion adaptively changes to the change in the size y of the shortest side. Especially when the chip size is small, if the radius of curvature of the chamfered portion is too small, it easily leads to damage to the epitaxial layer due to the small stealth dicing window in the channel intersection region. If the radius of curvature of the chamfered portion is too large, it leads to a loss of a larger light-emitting area, thereby reducing luminous efficiency.

A light-emitting device, which adopts the light-emitting diode chip provided in any of the above embodiments, is further provided in the disclosure. The light-emitting device adopting the above-mentioned light-emitting diode chip has good reliability.

The technical solutions of the disclosure will be clearly and fully described below through various specific implementations in conjunction with the accompanying drawings in the embodiments of the disclosure.

### Embodiment 1

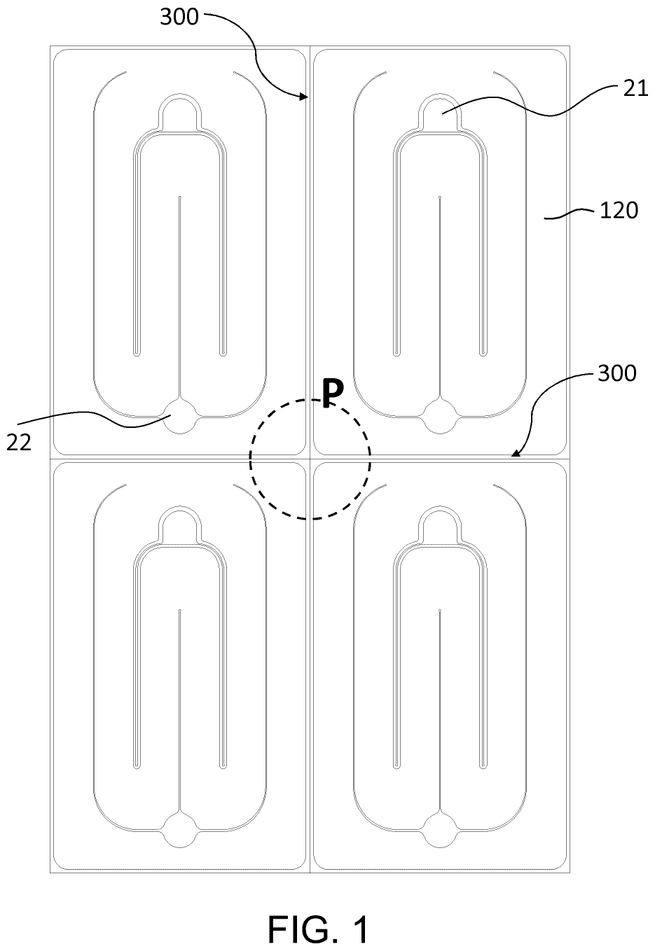

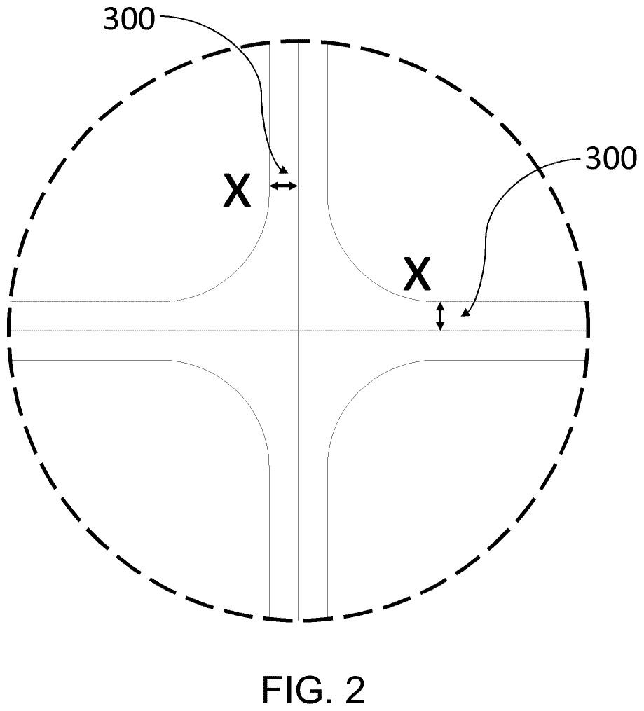

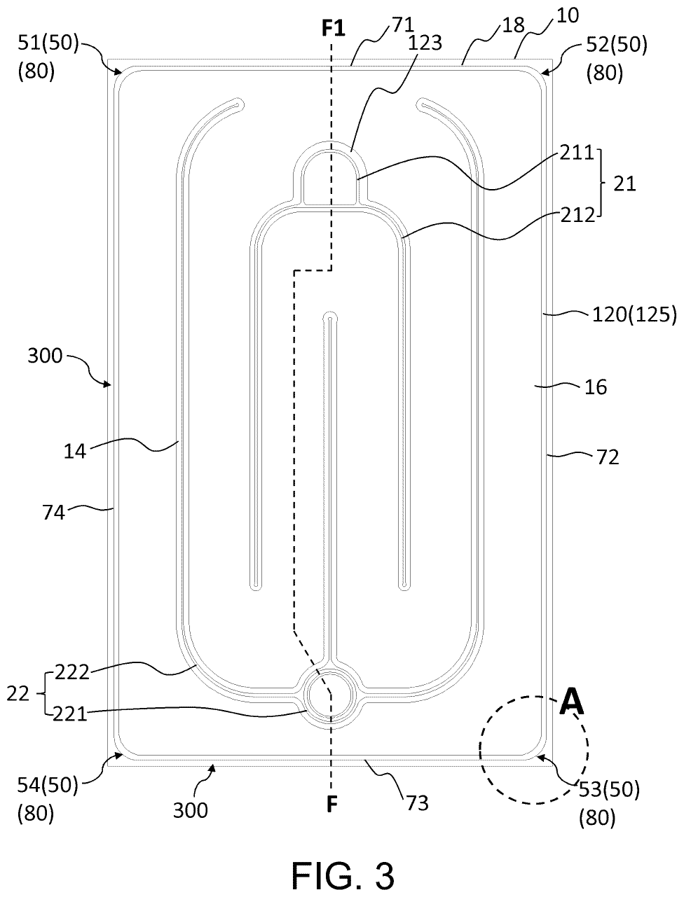

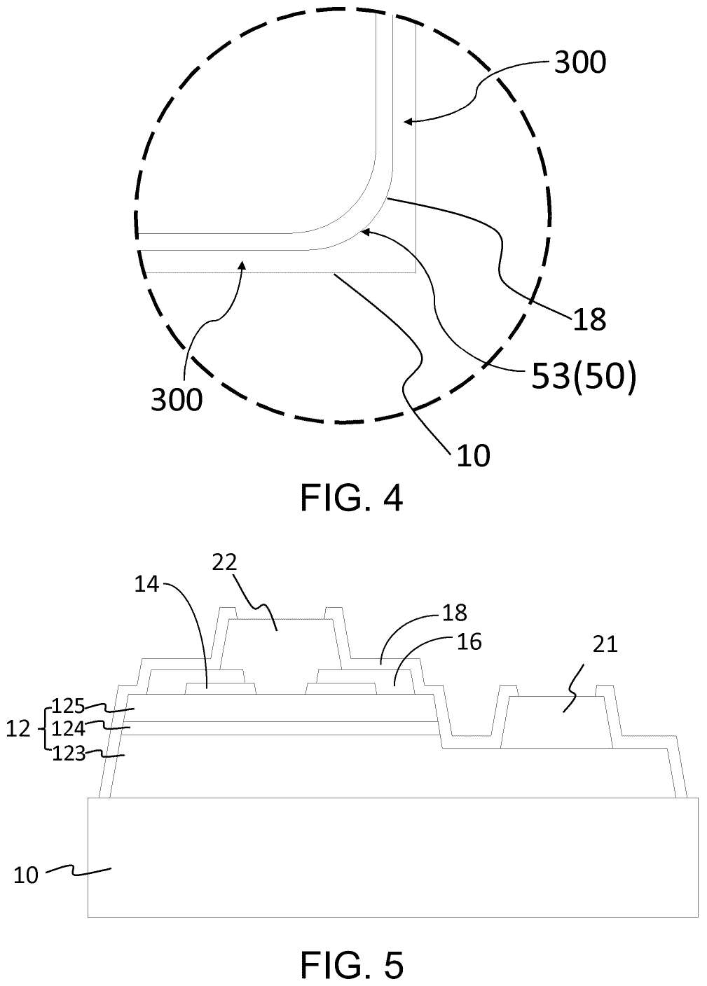

Referring to FIG. 1 to FIG. 5, FIG. 1 is a schematic diagram of a channel, FIG. 2 is a partially enlarged schematic diagram of position P in FIG. 1, FIG. 3 is a top view of a structural schematic diagram of the light-emitting diode chip provided in Embodiment 1 of the disclosure, FIG. 4 is a partially enlarged schematic diagram of region A in FIG. 3, FIG. 5 is a cross-sectional structural schematic diagram along the F-F1 direction in FIG. 3. The embodiment 1 of the disclosure provides a light-emitting diode. As shown in the figures, the light-emitting diode chip may include a semiconductor stack 12, a channel 300, a first electrode 21, and a second electrode 22.

The semiconductor stack 12 is disposed on the substrate 10. The substrate 10 may be an insulating substrate. Preferably, the substrate 10 may be made of a transparent material or a translucent material. In the illustrated embodiment, the substrate 10 is a sapphire substrate. In some embodiments, the substrate 10 may be a patterned sapphire substrate, but this disclosure is not limited thereto. The substrate 10 may also be made of a conductive material or a semiconductor material. For example, the material of the substrate 10 may include at least one of silicon carbide, silicon, magnesium aluminum oxide, magnesium oxide, lithium aluminum oxide, aluminum gallium oxide, and gallium nitride.

The semiconductor stack 12 includes a first semiconductor layer 123, a light-emitting layer 124, and a second semiconductor layer 125. That is, the light-emitting layer 124 is located between the first semiconductor layer 123 and the second semiconductor layer 125. A portion of the upper surface of the first semiconductor layer 123 is not covered by the light-emitting layer 124, forming a mesa. The mesa is mainly used for disposing electrodes. The semiconductor stack 12 is divided into multiple independent semiconductor stacked structures 120. The semiconductor stacked structures 120 respectively correspond to multiple first electrodes 21 and multiple second electrodes 22. The channel 300 is formed between adjacent semiconductor stacked structures 120. The channel 300 surrounds the semiconductor stacked structure 120.

The first semiconductor layer 123 may be an N-type semiconductor layer, and may provide electrons to the light-emitting layer 124 under the influence of a power source. In some embodiments, the first semiconductor layer 123 includes an N-type doped nitride layer. The N-type doped nitride layer may include one or more N-type impurities of Group IV elements. N-type impurities may include one of Si, Ge, Sn, or a combination thereof. In some embodiments, a buffer layer may be disposed between the N-type semiconductor layer and the substrate 10 to alleviate the lattice mismatch between the substrate 10 and the N-type semiconductor layer. The buffer layer may include an un-doped AlN layer (abbreviated as u-AlN) or an un-doped AlGaN layer (abbreviated as u-AlGaN). The N-type semiconductor layer may also be connected to the substrate 10 through an adhesive layer.

The light-emitting layer 124 may be a quantum well structure (abbreviated as QW). In some embodiments, the light-emitting layer 124 may also be a multiple quantum well structure (abbreviated as MQW). The multiple quantum well structure includes multiple quantum well layers and multiple quantum barrier layers disposed alternately in a repetitive manner. For example, it may be a multiple quantum well structure such as GaN/AlGaN, InAlGaN/InAlGaN, or InGaN/AlGaN. In addition, the composition and thickness of the well layer within the light-emitting layer 124 determine the wavelength of the generated light. In order to improve the luminous efficiency of the light-emitting layer 124, this may be achieved by modifying the depth of the quantum wells, the number of layers of paired quantum wells and quantum barriers, their thicknesses, and/or other characteristics within the light-emitting layer 124.

The second semiconductor layer 125 may be a P-type semiconductor layer, and may provide holes to the light-emitting layer 124 under the influence of a power source. In some embodiments, the second semiconductor layer 125 includes a P-type doped nitride layer. The P-type doped nitride layer may include one or more P-type impurities of Group II elements. P-type impurities may include one of Mg, Zn, Be, or a combination thereof.

Although the first semiconductor layer 123 and the second semiconductor layer 125 may respectively be a single-layer structure, the disclosure is not limited thereto. The first semiconductor layer 123 and the second semiconductor layer 125 may also be a multi-layer structure. The multi-layer structure has different compositions and may also include superlattice layers. In addition, the disposition of the semiconductor stack is not limited thereto, and other types of semiconductor stacks may be selected according to actual requirements. For example, in other embodiments, in the case where the first semiconductor layer 123 is doped with P-type impurities, the second semiconductor layer 125 may be doped with N-type impurities. That is, the first semiconductor layer 123 is a P-type semiconductor layer, and the second semiconductor layer 125 is an N-type semiconductor layer.

The first electrode 21 is located on the first semiconductor layer 123. The first electrode 21 may be made of a metal material, which may be a single-layer metal structure, a double-layer metal structure, or a multi-layer metal structure, such as Ti/Al, Ti/Al/Ti/Au, Ti/Al/Ni/Au, V/Al/Pt/Au, and other metal stacked structures. In some embodiments, the first electrode 21 may be directly formed on the mesa of the first semiconductor layer 123 to form a good ohmic contact with the first semiconductor layer 123. In some embodiments, the first electrode 21 includes a first electrode pad 211 and at least one first electrode extension portion 212. The first electrode pad 211 is connected to the first electrode extension portion 212, and the first electrode extension portion 212 extends from the first electrode pad 211 toward the second electrode 22, so that the current may be spread evenly. In this embodiment, the first electrode 21 includes a first electrode pad 211 and two first electrode extension portions 212, in which the first electrode extension portion 212 has a strip-shaped structure.

The second electrode 22 is located on the second semiconductor layer 125. The second electrode 22 may be made of a metal material. The second electrode 22 may be made of the same or similar material as the first electrode 21. The second electrode 22 may also be made of a material different from the first electrode 21. In some embodiments, the second electrode 22 may include a second electrode pad 221 and a second electrode extension portion 222. The second electrode pad 221 is connected to the second electrode extension portion 222, and the second electrode extension portion 222 extends from the second electrode pad 221 toward the first electrode pad 211, so that the current may be spread evenly. In this embodiment, the second electrode 22 includes a second electrode pad 221 and three second electrode extension portions 222, in which the second electrode extension portion 222 has a strip-shaped structure.

When viewed from above the light-emitting diode chip toward the semiconductor stack 12, any semiconductor stacked structure 120 has at least one chamfered portion 50 located in the channel 300, and a range of a radius of curvature of the chamfered portion 50 is from 5 to 50 microns (micrometers). By expanding the radius of curvature of the chamfered portion 50 of the LED chip epitaxial layer located at the intersection position of the channel 300, expanding the stealth dicing window in the channel intersection region, damage to the epitaxial layer caused by laser energy during stealth dicing may be effectively avoided, preventing electrical abnormalities caused by damage to the chip structure. Therefore, the purpose of enhancing chip reliability is achieved, thereby greatly improving product yield and reducing manufacturing costs.

In some embodiments, the minimum width of the channel 300 is x microns. The range of the radius of curvature of the chamfered portion 50 increases as the width of the channel 300 decreases. Furthermore, in some embodiments, when the width of the channel 300 is x μm≤4 μm, the range of the radius of curvature of the chamfered portion 50 is from 15 to 12x μm. For example, when x μm=3 μm, the range of the radius of curvature of the chamfered portion 50 may be from 15 to 36 μm. Preferably, when x μm=3 μm, the range of the radius of curvature of the chamfered portion 50 is from 25 to 30 μm. In some embodiments, when the range of the width of the channel 300, x μm, is from 4 μm<x μm≤7 μm, the range of the radius of curvature of the chamfered portion 50 is from 15 to 6x μm. For example, when x μm=6 μm, the range of the radius of curvature of the chamfered portion 50 may be from 15 to 36 μm. Preferably, when x μm=6 μm, the range of the radius of curvature of the chamfered portion 50 is from 20 to 25 μm. In some embodiments, when the range of the width of the channel 300, x μm, is from 7 μm<x μm≤12 μm, the range of the radius of curvature of the chamfered portion 50 is from 5 to 3x μm. For example, when x μm=10 μm, the range of the radius of curvature of the chamfered portion 50 may be from 5 to 30 μm. Preferably, when x μm=10 μm, the range of the radius of curvature of the chamfered portion 50 is from 5 to 20 μm. In some embodiments, when the width of the channel 300 is x μm>12 μm, the range of the radius of curvature of the chamfered portion 50 is from 5 to 2x μm. For example, when x μm=14 μm, the range of the radius of curvature of the chamfered portion 50 may be from 5 to 28 μm. Preferably, when x μm=14 μm, the range of the radius of curvature of the chamfered portion 50 is from 5 to 15 μm. The radius of curvature of the chamfered portion 50 is in an inverse proportion to the width of the channel 300, and chamfered portions 50 with different radius of curvature are correspondingly disposed for channels 300 with different widths. When the width of the channel 300 is designed to be small, the epitaxial layer is easily damaged due to the small stealth dicing window in the channel intersection region. Therefore, the stealth dicing window of the channel intersection region is expanded by disposing a relatively larger chamfered portion. This may effectively prevent damage to the epitaxial layer caused by laser energy during stealth dicing, thereby improving the reliability of the chip. When the width of the channel 300 is designed to be larger, the stealth dicing window in the channel intersection region already has a certain width, so a relatively smaller chamfered portion may be disposed. This may improve the reliability of the chip while ensuring the effective light-emitting area of the chip, thereby improving the luminous efficiency of the LED chip. In addition, the radii of curvature of multiple chamfered portions 50 of the same semiconductor stacked structure 120 may be equal or unequal. In this embodiment, the radii of curvature of the chamfered portions 50 of the same semiconductor stacked structure 120 are equal. When viewed from above the light-emitting diode chip toward the semiconductor stack 12, the semiconductor stacked structure 120 has four sides and four chamfered portions 50. As shown in the drawings, four sides and four chamfered portions 50 are sequentially defined in a circumferential direction as a first side 71, a first chamfered portion 51, a second side 72, a second chamfered portion 52, a third side 73, a third chamfered portion 53, a fourth side 74, and a fourth chamfered portion 54. The radius of curvature of the first chamfered portion 51, the radius of curvature of the second chamfered portion 52, the radius of curvature of the third chamfered portion 53, and the radius of curvature of the fourth chamfered portion 54 are all equal.

In some embodiments, the semiconductor stacked structure 120 has a shortest side (taking this embodiment as an example, the shortest sides are the first side 71 and the third side 73), and the size of the shortest side is y microns. When viewed from above the light-emitting diode chip toward the semiconductor stack 12, any semiconductor stacked structure 120 has at least one chamfered portion 50, and a range of a radius of curvature of the chamfered portion 50 is from 5 to y/3 microns. The range of the radius of curvature of the chamfered portion 50 changes correspondingly as the size y of the shortest side changes. Especially when the chip size is small, if the radius of curvature of the chamfered portion 50 is too small, the epitaxial layer may be easily damaged due to the small stealth dicing window in the intersection region of the channel 300. If the radius of curvature of the chamfered portion 50 is too large, it leads to a loss of a larger light-emitting area, thereby reducing luminous efficiency.

The current blocking layer 14 is located on the second semiconductor layer 125 and is configured to block current from vertically flowing from the upper electrode 22 into the second semiconductor layer 125. As an example, the current blocking layer 14 is a transparent insulating material, including at least one of transparent inorganic insulating materials such as silicon oxide, silicon nitride, silicon oxynitride, titanium oxide, or aluminum oxide. The current blocking layer 14 may also be a single layer or an alternating multi-layer structure. The single layer may have a higher light transmittance, such as a material with a light transmittance higher than 80%, such as silicon oxide. The current blocking layer 14 may also be a reflective material formed by a combination of multi-layer structures, for example, a material with a reflectivity higher than 60%, such as a Bragg reflector. The thickness of the current blocking layer 14 may be selected from any thickness between 50 nm and 500 nm, but the embodiment of the disclosure is not limited thereto. In some embodiments, the current blocking layer 14 may be continuously distributed or intermittently distributed. The continuously distributed current blocking layer may effectively improve the effect of blocking current from vertically flowing from the upper electrode 22 into the second semiconductor layer 125. The intermittently distributed current blocking layer may increase the contact between the electrode 22 and the epitaxial layer, improve the adhesion of the electrode 22, and improve the wiring ability, but the embodiment of the disclosure is not limited to this. Furthermore, in some embodiments, the current blocking layer 14 may also be disposed between the first electrode 21 and the first semiconductor layer 123, but the embodiments of the disclosure are not limited thereto.

A transparent conductive layer 16 is located on the second semiconductor layer 125 and is configured to guide current from the upper electrode 22 to be injected into the second semiconductor layer 125 more uniformly, thereby achieving a current expansion effect. As an example, the transparent conductive material may include indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), tungsten doped indium oxide (IWO), or zinc oxide (ZnO), but the embodiments of the disclosure are not limited thereto.

In some embodiments, the light-emitting diode chip further includes a protective layer 18 covering the sidewalls and a portion of the upper surface of the semiconductor stack 12, the transparent conductive layer 16, the first electrode 21, and the second electrode 22. The protective layer 18 has an opening, and the first electrode 21 and the second electrode 22 are located in the opening of the protective layer 18 to facilitate subsequent bonding wire connection. The protective layer 18 has different functions depending on the position involved. For example, the sidewall of the epitaxial layer are covered to prevent the leakage of conductive materials that causes the first semiconductor layer 123 and the second semiconductor layer 125 to be electrically connected. This reduces the short circuit abnormality of the light-emitting diode chip, but the embodiments of the disclosure are not limited thereto. In some embodiments, the material of protective layer 18 includes a non-conductive material. The non-conductive material is preferably an inorganic material or a dielectric material. The inorganic material includes silicone or glass. The dielectric material including aluminum oxide (AlO), silicon nitride (SiNx), silicon oxide (SiOx), titanium oxide (TiOx), or magnesium fluoride (MgFx) may be an electrically insulating material. For example, the protective layer 18 may be silicon dioxide, silicon nitride, titanium oxide, tantalum oxide, niobium oxide, barium titanate or a combination thereof. The combination may be, for example, a Bragg reflector (DBR) formed by repeated stacking of two materials. The protective layer 18 covers the semiconductor stack 12. The protective layer 18 has at least one chamfered edge 80. The radius of curvature of the chamfered portion 50 is equal to the radius of curvature of the chamfered edge 80. By synchronizing the chamfered edge 80 with a radius of curvature equal to the radius of curvature of the chamfered portion 50 on the protective layer 18, it is possible to simultaneously prevent the laser energy from contacting the protective layer 18 during stealth dicing, causing the protective layer 18 to rupture and cause edge or corner chipping, thereby ensuring the protective effect of the protective layer 18 on the entire light-emitting diode chip and further improving the reliability of the chip.

### Embodiment 2

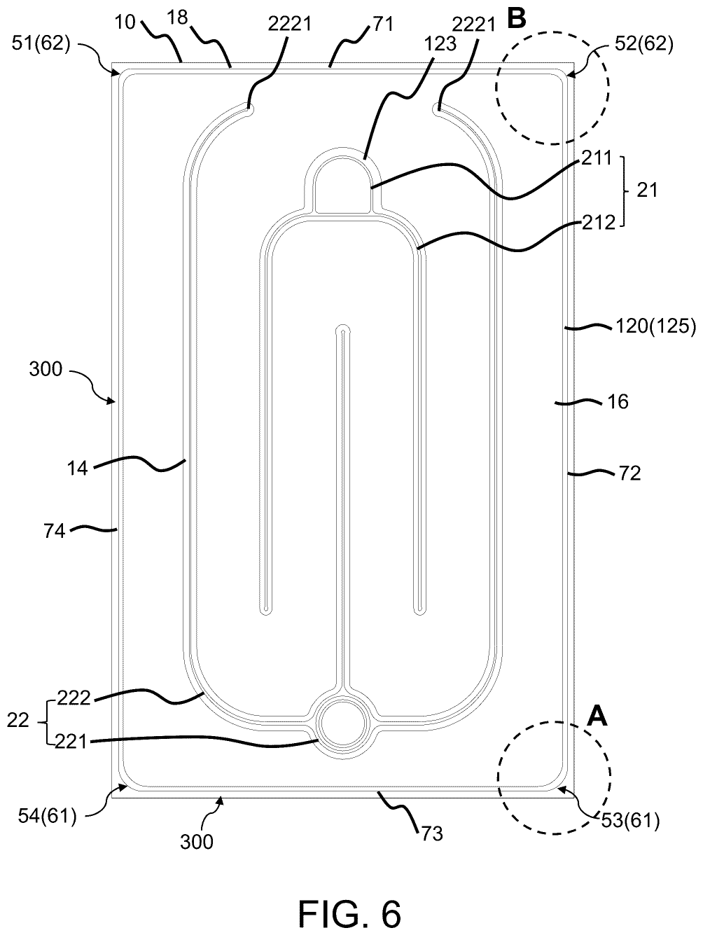

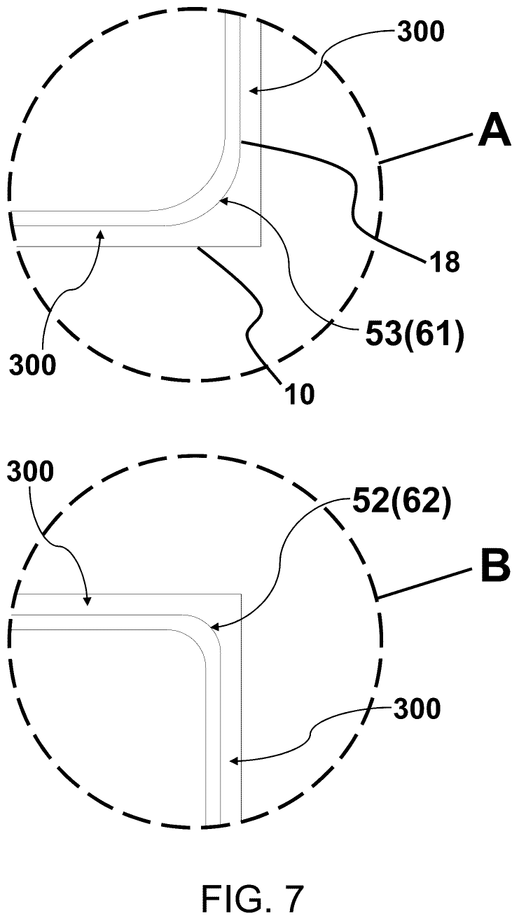

Referring to FIG. 6 and FIG. 7, FIG. 6 is a top view of a structural schematic diagram of the light-emitting diode chip provided in the embodiment 2 of the disclosure, FIG. 7 is a partial enlarged comparison schematic diagram of region A and region B in FIG. 6. Compared with the light-emitting diode chip of the embodiment 1 of FIG. 1, the main difference of the light-emitting diode chip of the embodiment 2 is that in this embodiment, the chamfered portions 50 of the semiconductor stacked structure 120 have unequal radii of curvature. Specifically, the radii of curvature of the chamfered portions 50 of the same semiconductor stacked structure 120 may gradually increase as the distance from the first electrode 21 increases. More specifically, the first electrode 21 refers to the first electrode pad 211. There is a distance from the chamfered portion to the first electrode pad 211, and the radius of curvature of the chamfered portions of the same semiconductor stacked structure gradually increase as the distance increases. The distance is the shortest distance between the chamfered portion and the first electrode pad 211. Alternatively, the radii of curvature of the chamfered portions 50 of the same semiconductor stacked structure 120 gradually increase as the distance from the end portion 2221 of the second electrode extension portion 222 increases. There is a distance from the chamfered portion to the end portion 2221 of the second electrode extension portion 222, and the radius of curvature of the chamfered portions of the same semiconductor stacked structure gradually increase as the distance increases. The distance is the shortest distance between the chamfered portion and the end portion 2221 of the second electrode extension portion 222. Since the position close to the end portion 2221 of the first electrode pad 211 or the second electrode extension portion 222 is often a high current density region, while the position away from the end portion 2221 of the first electrode pad 211 or the second electrode extension portion 222 is often a low current density region, by setting the radius of curvature of the chamfered portion 50 close to the high current density region to be smaller than the radius of curvature of the chamfered portion 50 close to the low current density region, that is, setting a chamfered portion with a smaller radius of curvature in the high current density region, this may ensure that the reliability of the chip may be improved while also improving the current expansion capability of the high current density region and reduce the loss of the effective light-emitting area of the chip, thereby further improving the photoelectric performance of the light-emitting diode chip. When viewed from above the light-emitting diode chip toward the semiconductor stack 12, the semiconductor stacked structure 120 has at least one first type chamfered portion 61 and at least one second type chamfered portion 62. The distance between the first type chamfered portion 61 and the first electrode pad 211 is less than the distance between the second type chamfered portion 62 and the first electrode pad 211. The radius of curvature of the first type chamfered portion 61 may be less than the radius of curvature of the second type chamfered portion 62. Specifically, the distance is the shortest distance between the chamfered portion and the first electrode pad 211. In this embodiment, the semiconductor stacked structure 120 has two first type chamfered portions 61 and two second type chamfered portions 62. As shown in FIG. 6, the first chamfered portion 51 and the second chamfered portion 52 are equidistant from the first electrode pad 211, and the third chamfered portion 53 and the fourth chamfered portion 54 are equidistant from the first electrode pad 211. Relative to the third chamfered portion 53 and the fourth chamfered portion 54, the first chamfered portion 51 and the second chamfered portion 52 are closer to the first electrode pad 211. The first chamfered portion 51 and the second chamfered part 52 are defined as the first type chamfered part 61, the third chamfered portion 53 and the fourth chamfered portion 54 are defined as the second type chamfered portion 62. The radius of curvature of the first chamfered portion 51 and the second chamfered portion 52 may be less than the radius of curvature of the third chamfered portion 53 and the fourth chamfered portion 54. Relative to the third chamfered portion 53 and the fourth chamfered portion 54, the first chamfered portion 51 and the second chamfered portion 52 are also closer to the end portion 2221 of the second electrode extension portion 222.

Furthermore, in some embodiments, a range of the radius of curvature of the first type chamfered portion 61 is from 5 to 50 microns, and a range of the radius of curvature of the second type chamfered portion 62 is from 5 to 50 microns. The ratio of the radius of curvature ratio of the first type chamfered portion 61 to the radius of curvature ratio of the second type chamfered portion 62 is 0.5 to 1. For example, the radius of curvature of the first type chamfered portion 61 may be set to 20 microns, and the radius of curvature of the second type chamfered portion 62 may be set to 10 microns. By limiting the ratio of the radius of curvature of the chamfered portion near the high current density region and the low current density region, it is possible to improve the reliability of the chip while ensuring more effective light-emitting area, thereby further improving the photoelectric performance of the light-emitting diode chip.

### Embodiment 3

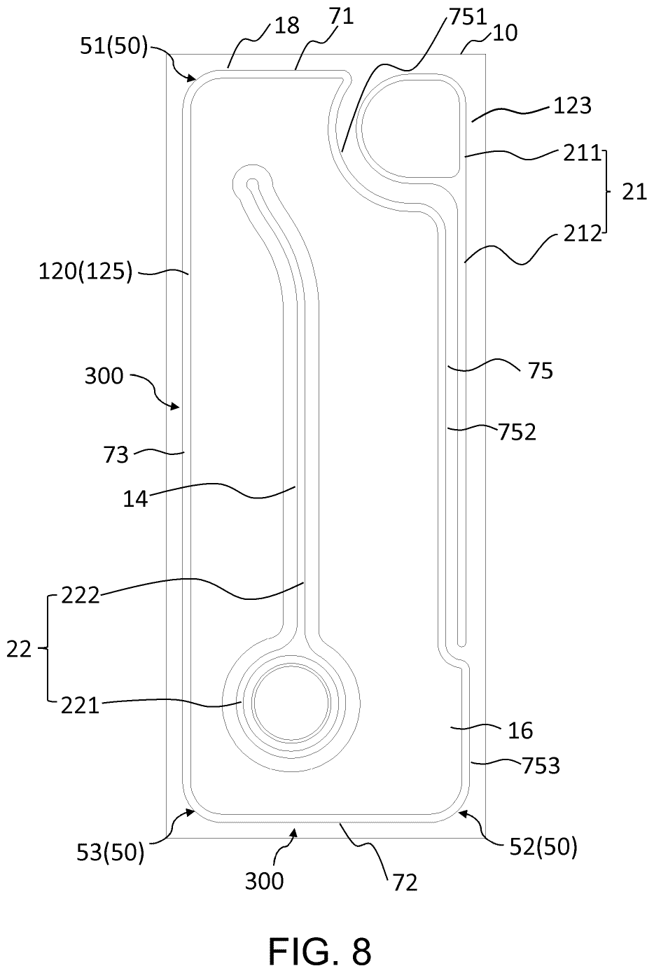

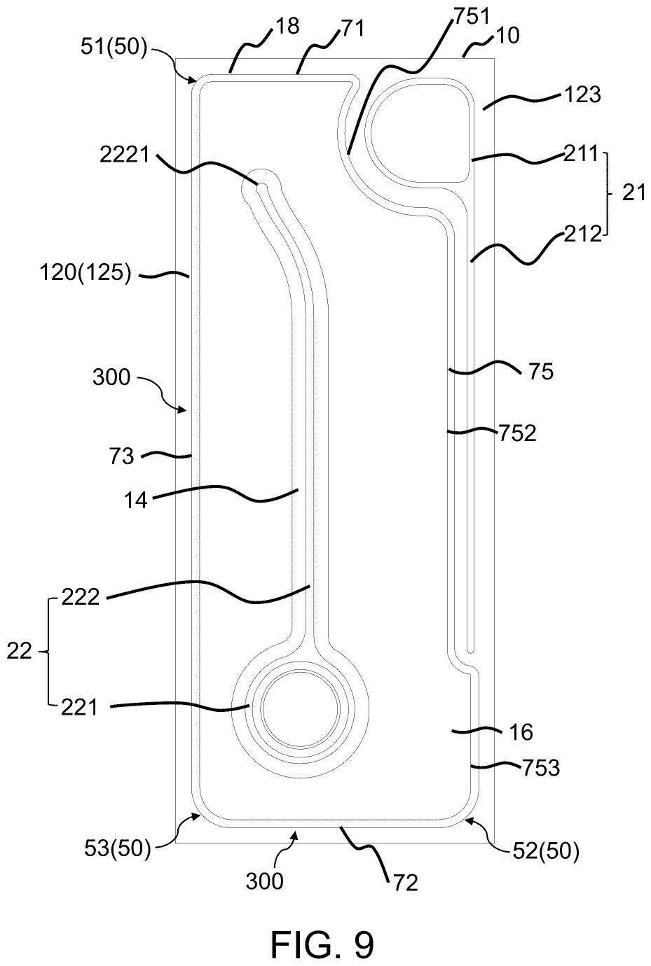

Referring to FIG. 8 to FIG. 9, FIG. 8 is a top view of a structural schematic diagram of the light-emitting diode chip provided in the embodiment 3 of the disclosure, FIG. 9 is a top view of a structural schematic diagram of another light-emitting diode chip provided in the embodiment 3 of the disclosure. Compared with the light-emitting diode chip of the embodiment 1 of FIG. 1, the main difference of the light-emitting diode chip of the embodiment 3 is that the first electrode 21 includes a first electrode pad 211 and a first electrode extension portion 212, and the second electrode 22 includes a second electrode pad 221 and a second electrode extension portion 222. When viewed from above the light-emitting diode chip toward the semiconductor stack 12, the semiconductor stacked structure 120 has one curved edge, three sides, and three chamfered portions 50. In a circumferential direction, they are in a sequence of the first chamfered portion 51, the first side 71, the curved edge 75, the second chamfered portion 52, the second side 72, the third chamfered portion 53, and the third side 73. The curved side 75 includes an arc side 751, a long side 752, and a short side 753. The two ends of the arc side 751 are respectively connected to the first side 71 and the long side 752, the two ends of the long side 752 are respectively connected to the arc side 751 and the short side 753, and the two ends of the short side 753 are respectively connected to the long side 752 and the second chamfered portion 52. That is, the first side 71, the arc side 751, the long side 752, the short side 753, and the second chamfered portion 52 are along the circumferential direction in sequence.

Referring to FIG. 8, in this embodiment, the radii of curvature of the chamfered portions 50 of the same semiconductor stacked structure 120 are equal. Specifically, the radius of curvature of the first chamfered portion 51, the radius of curvature of the second chamfered portion 52, and the radius of curvature of the third chamfered portion 53 are all equal.

Furthermore, in some embodiments, referring to FIG. 9, the radii of curvature of multiple chamfered portions 50 of the same semiconductor stacked structure 120 may also be unequal. Specifically, the radii of curvature of the chamfered portions 50 of the same semiconductor stacked structure 120 may gradually increase as the distance from the first electrode 21 increases. More specifically, the first electrode 21 refers to the first electrode pad 211, and there is a distance from the chamfered portion to the first electrode pad 211. The radius of curvature of the chamfered portions of the same semiconductor stacked structure gradually increase as the distance increases. The distance is the shortest distance between the chamfered portion and the first electrode pad 211. Alternatively, the radii of curvature of the chamfered portions 50 of the same semiconductor stacked structure 120 gradually increases as the distance from the end portion 2221 of the second electrode extension portion 222 increases. There is a distance from the chamfered portion to the end portion 2221 of the second electrode extension portion 222. The radius of curvature of the chamfered portions of the same semiconductor stacked structure gradually increase as the distance increases. The distance is the shortest distance between the chamfered portion and the end portion 2221 of the second electrode extension portion 222. For example, the radius of curvature of the first chamfered portion 51 may be set to 10 microns, and the radius of curvature of the second chamfered portion 52 and the third chamfered portion 53 may be set to 20 microns, thereby improving the reliability of the chip while ensuring more effective light-emitting area, thereby further improving the photoelectric performance of the light-emitting diode chip.

### Embodiment 4

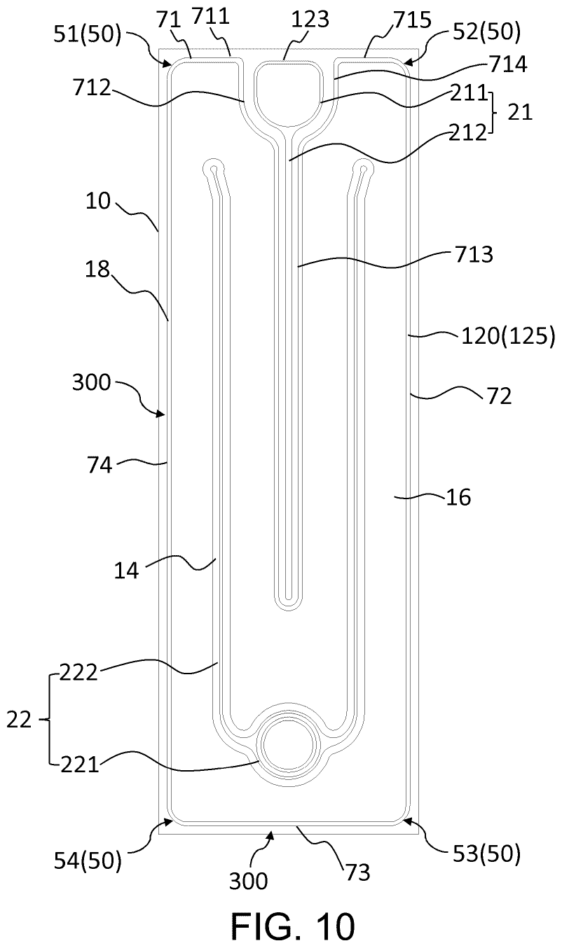

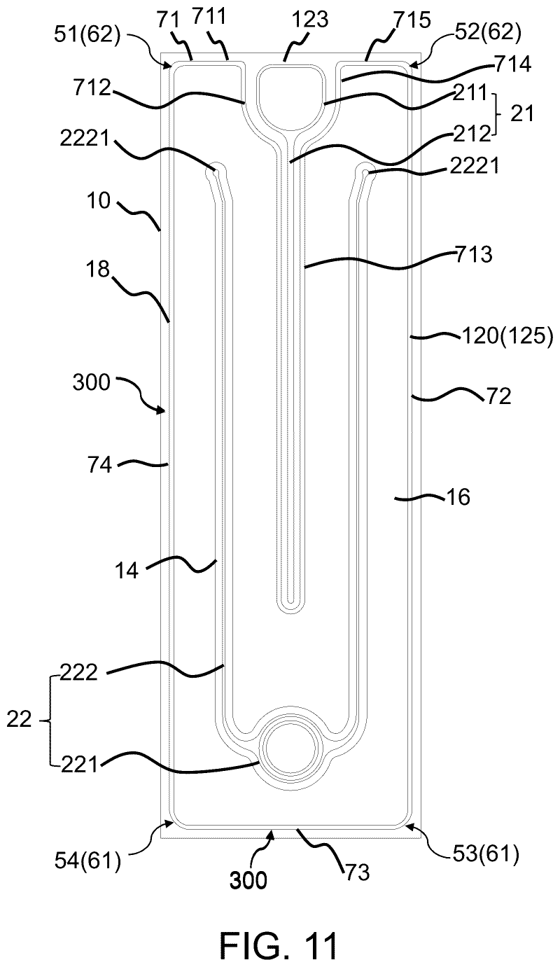

Referring to FIG. 10 to FIG. 11, FIG. 10 is a top view of a structural schematic diagram of the light-emitting diode chip provided in the embodiment 4 of the disclosure, FIG. 11 is a top view of a structural schematic diagram of another light-emitting diode chip provided in the embodiment 4 of the disclosure. Compared with the light-emitting diode chip of the embodiment 1 of FIG. 1, the main difference of the light-emitting diode chip of the embodiment 4 is that the first electrode 21 includes a first electrode pad 211 and a first electrode extension portion 212, and the second electrode 22 includes a second electrode pad 221 and two second electrode extension portions 222. The first side 71 sequentially includes a short side 711, an arc side 712, an arc side 713, an arc side 714, and a short side 715 along the circumferential direction. The two ends of the short side 711 are respectively connected to the first chamfered portion 51 and the arc side 712, and the two ends of the short side 715 are respectively connected to the arc side 714 and the second chamfered portion 52.

Referring to FIG. 10, in this embodiment, the radii of curvature of the chamfered portions 50 of the same semiconductor stacked structure 120 are equal. The radius of curvature of the first chamfered portion 51, the radius of curvature of the second chamfered portion 52, the radius of curvature of the third chamfered portion 53, and the radius of curvature of the fourth chamfered portion 54 are all equal.

Referring to FIG. 11, the radii of curvature of multiple chamfered portions 50 of the same semiconductor stacked structure 120 may also be unequal. As show in the drawings, relative to the third chamfered portion 53 and the fourth chamfered portion 54, the first chamfered portion 51 and the second chamfered portion 52 are closer to the first electrode pad 211/the end portion 2221 of second electrode extension portion 222. For example, the radius of curvature of the first chamfered portion 51 and the second chamfered portion 52 may be set to 10 microns, and the radius of curvature of the third chamfered portion 53 and the fourth chamfered portion 54 may be set to 20 microns. This may improve the reliability of the chip while ensuring more effective light-emitting area, thereby further improving the photoelectric performance of the light-emitting diode chip.

### Embodiment 5

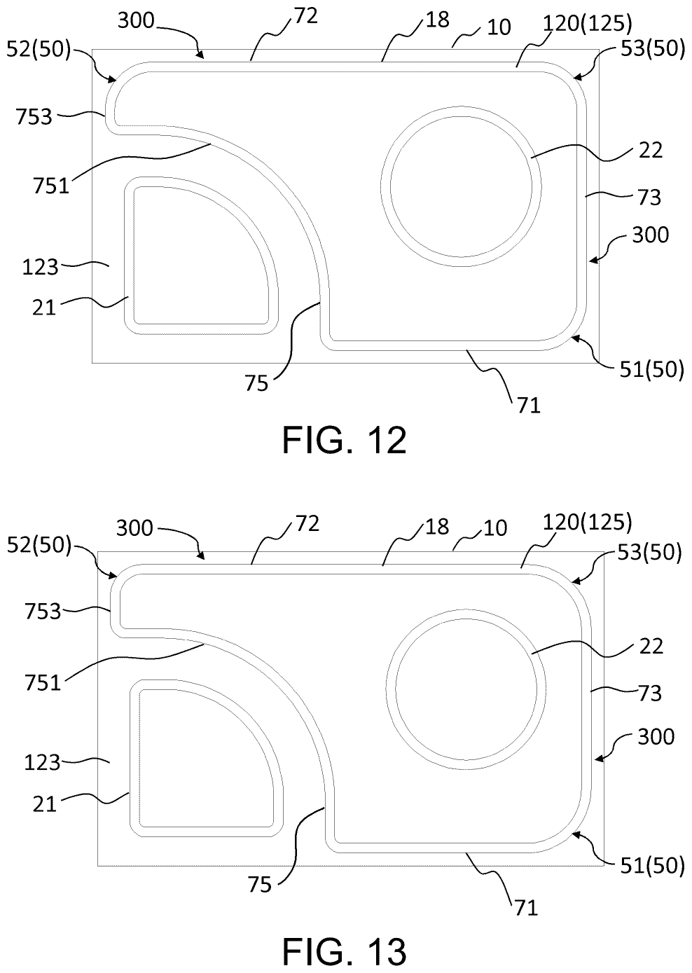

Referring to FIG. 12 to FIG. 13, FIG. 12 is a top view of a structural schematic diagram of the light-emitting diode chip provided in the embodiment 5 of the disclosure, FIG. 13 is a top view of a structural schematic diagram of another light-emitting diode chip provided in the embodiment 5 of the disclosure. Compared with the light-emitting diode chip of the embodiment 3 of FIG. 8 to FIG. 9, the main difference of the light-emitting diode chip of the embodiment 5 is that the first electrode 21 and the second electrode 22 do not include the electrode extension portion. When viewed from above the light-emitting diode chip toward the semiconductor stack 12, the semiconductor stacked structure 120 has three sides, one curved side, and three chamfered portions 50. In a circumferential direction, they are in a sequence of the first chamfered portion 51, the first side 71, the curved edge 75, the second chamfered portion 52, the second side 72, the third chamfered portion 53, and the third side 73. The curved side 75 includes an arc side 751 and a short side 753. The two ends of the arc side 751 are respectively connected to the first side 71 and the short side 753, and the two ends of the short side 753 are respectively connected to the arc side 751 and the second chamfered portion 52. That is, the first side 71, the arc side 751, the short side 753, and the second chamfered portion 52 are along the circumferential direction in sequence.

Referring to FIG. 12, in this embodiment, the radii of curvature of the chamfered portions 50 of the same semiconductor stacked structure 120 are equal. The radius of curvature of the first chamfered portion 51, the radius of curvature of the second chamfered portion 52, and the radius of curvature of the third chamfered portion 53 are all equal.

Referring to FIG. 13, the radius of curvature of multiple chamfered portions of the same semiconductor stacked structure 120 may also be unequal. For example, the radius of curvature of the second chamfered portion 52 may be set to 10 microns and the radius of curvature of the first chamfered portion 51 and the third chamfered portion 53 may be set to 20 microns according to different distances from the chamfered portion 50 to the first electrode pad 211/the end portion of the second electrode extension portion 222. This may improve the reliability of the chip while ensuring more effective light-emitting area, thereby further improving the photoelectric performance of the light-emitting diode chip.

### Embodiment 6

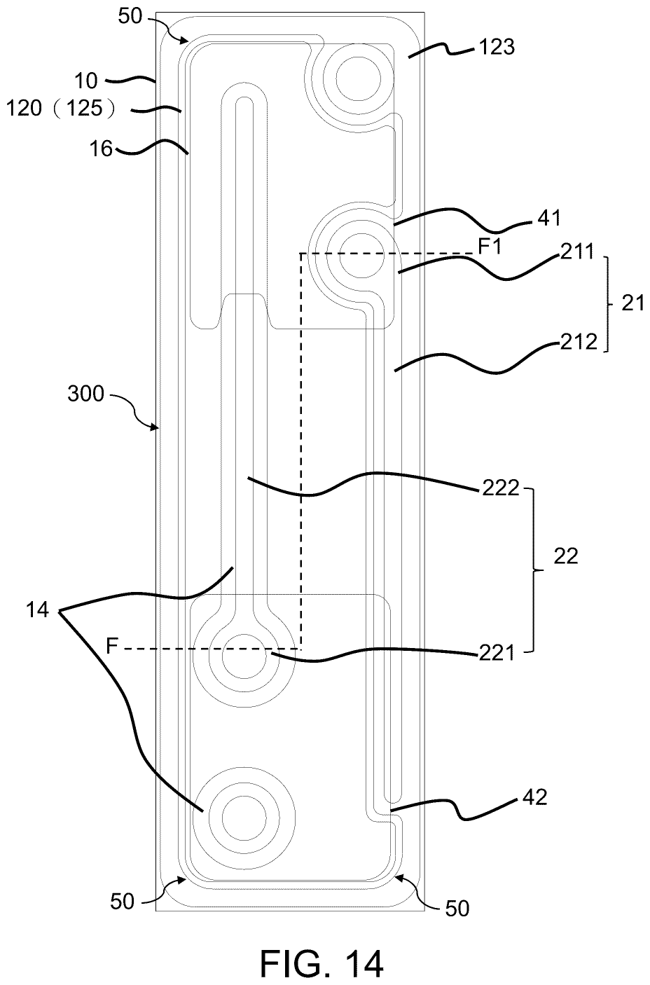

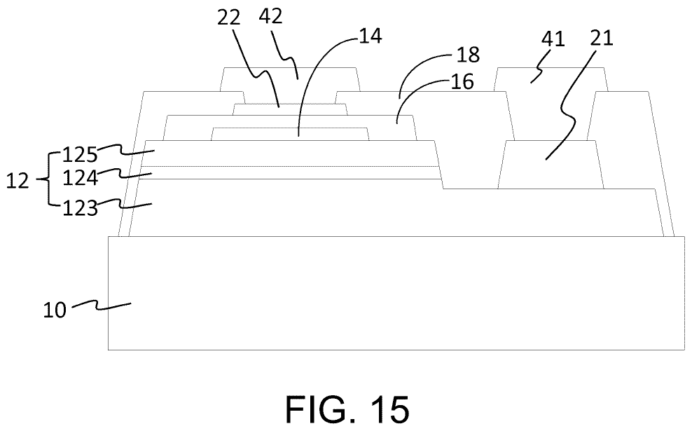

Referring to FIG. 14 to FIG. 15, FIG. 14 is a top view of a structural schematic diagram of the light-emitting diode chip provided in Embodiment 6 of the disclosure, FIG. 15 is a cross-sectional structural schematic diagram along the F-F1 direction in FIG. 14. Compared with the light-emitting diode chip of the embodiment 1 in FIG. 1, the main difference of the light-emitting diode chip of the embodiment 6 is that the light-emitting diode chip of this embodiment is a flip-chip structure diode. The light-emitting diode chip also includes a first bonding pad 41 and a second bonding pad 42, which are respectively connected to the first electrode 21 and the second electrode 22 through the opening of the protective layer 18. The light-emitting diode chip of the embodiment 1 is a conventional-orientation structure diode. The radii of curvature of multiple chamfered portions 50 of the same semiconductor stacked structure 120 may be equal or unequal, which may be described with reference to the previous embodiments, and are not repeated herein.

The light-emitting diode chips provided by the above embodiments are not only suitable for chips with a conventional-orientation structure as shown in FIG. 2 and a chip with a flip-chip structure as shown in FIG. 15, but are also suitable for chips with a high-voltage structure. The high-voltage structure chip includes multiple light-emitting units. Adjacent light-emitting units are isolated from each other through isolation trenches on the substrate, and are electrically connected through interconnection electrodes spanning across the isolation trenches. Concave and convex surface structures as described in the above embodiments are selectively disposed on the sidewalls of the semiconductor light-emitting sequence stacked layer. For the specific structure, performance, and advantages, reference may be made to the foregoing content and are not repeated herein.

A light-emitting device, which adopts the light-emitting diode chip provided in any of the above embodiments, is further provided in the disclosure. The size of the light-emitting diode may be a micro LED, a mini LED, or a conventional LED. Light-emitting diodes may be used in backlight displays or RGB displays. Small-sized flip-chip light-emitting diodes may be integrated and installed in quantities of hundreds, thousands, or tens of thousands on application substrates or packaging substrates, forming the light-emitting source component of backlight display devices or RGB display devices.

The aforementioned chamfered portion 50 and chamfered edge 80 may be an arc. It should be added that due to the influence of factors such as differences in the photoresist, the line described in the disclosure is not necessarily a perfectly straight line. It also encompasses situations that may occur during manufacturing, such as slight bulging or curvature of the straight edges. The arc described in the disclosure is not necessarily an arc from a perfect circle, but also encompasses situations that may occur during manufacturing, such as slight bulging or curvature of the arched edge. The equality expressed in this disclosure is understood in a broad sense (it is not an exact equality). For example, an error within 0.1 micron is allowed, such as a distance of 1 micron and a distance of 1.1 micron also belong to the equality of distances mentioned in this disclosure.

In summary, a light-emitting diode chip and a light-emitting device are provided by an embodiment of the disclosure. By optimizing the LED chip epitaxial layer corner positions of the channel intersection region through methods such as expanding the radius of curvature of the chamfered portion of the LED chip epitaxial layer located at the channel intersection position, or disposing chamfered portions with different radius of curvature on the epitaxial layer at different positions of the chip to expand the stealth dicing window in the channel intersection region, damage to the epitaxial layer caused by laser energy may be effectively prevented, thereby improving the reliability of the chip of the disclosure while ensuring more effective light-emitting area, thereby further improving the photoelectric performance of the light-emitting diode chip.

What is claimed is:

1. A light-emitting diode, comprising:
a semiconductor stacked structure, comprising a first semiconductor layer, a light-emitting layer, and a second semiconductor layer, the light-emitting layer being located between the first semiconductor layer and the second semiconductor layer;
a channel, surrounding the semiconductor stacked structure;
a first electrode, located on the first semiconductor layer;
a second electrode, located on the second semiconductor layer;
wherein when viewed from above the light-emitting diode toward the semiconductor stacked structure, the semiconductor stacked structure has at least one chamfered portion located on the channel, and a range of a radius of curvature of the at least one chamfered portion is from 5 microns to 50 microns.

2. The light-emitting diode according to claim 1, wherein the range of the radius of curvature of the at least one chamfered portion increases as a width of the channel decreases.

3. The light-emitting diode according to claim 1, wherein a width of the channel is x μm, x μm≤4 μm, and the range of the radius of curvature of the at least one chamfered portion is from 15μ m to 12x μ m.

4. The light-emitting diode according to claim 1, wherein a width of the channel is x μm, 4 μm<x μm≤7 μm, and the range of the radius of curvature of the at least one chamfered portion is from 15 μm to 6x μm.

5. The light-emitting diode according to claim 1, wherein a width of the channel is x μm, 7 μm<x μm≤12 μm, and the range of the radius of curvature of the at least one chamfered portion is from 5 μm to 3x μm.

6. The light-emitting diode according to claim 1, wherein a width of the channel is x μm, x μm>12 μm, and the range of the radius of curvature of the at least one chamfered portion is from 5 to 2x μm.

7. The light-emitting diode according to claim 1, further comprising a protective layer, the protective layer covering the semiconductor stacked structure, the protective layer having at least one chamfered edge, the radius of curvature of the at least one chamfered portion being equal to a radius of curvature of the at least one chamfered edge.

8. The light-emitting diode according to claim 1, wherein a number of the at least one chamfered portion of the semiconductor stacked structure is multiple, and the radii of curvature of the chamfered portions are equal or unequal.

9. The light-emitting diode according to claim 1, wherein when viewed from above the light-emitting diode toward the semiconductor stacked structure, the semiconductor stacked structure having a first side, a second side, a third side and a fourth side, and the at least one chamfered portion including a first chamfered portion, a second chamfered portion, a third chamfered portion and a fourth chamfered portion, the four sides and the four chamfered portions are sequentially arranged as the first side, the first chamfered portion, the second side, the second chamfered portion, the third side, the third chamfered portion, the fourth side, and the fourth chamfered portion in a circumferential direction, the radius of curvature of the first chamfered portion, the radius of curvature of the second chamfered portion, the radius of curvature of the third chamfered portion, and the radius of curvature of the fourth chamfered portion are all equal.

10. The light-emitting diode according to claim 1, wherein the at least one chamfered portion including a first chamfered portion, a second chamfered portion and a third chamfered portion when viewed from above the light-emitting diode toward the semiconductor stacked structure, the semiconductor stacked structure has the first chamfered portion, a first side, a curved edge, the second chamfered portion, a second side, the third chamfered portion and a third side arranged in sequence in a circumferential direction, the radius of curvature of the first chamfered portion, the radius of curvature of the second chamfered portion, and the radius of curvature of the third chamfered portion are all equal.

11. The light-emitting diode according to claim 8, the radii of curvature of the chamfered portions gradually increase as a distance from the first electrode increases.

12. The light-emitting diode according to claim 8, wherein the second electrode comprises at least one second electrode extension portion, and the radii of curvature of the of chamfered portions gradually increase as a distance from an end portion of the at least one second electrode extension portion increases.

13. The light-emitting diode according to claim 1, wherein the semiconductor stacked structure has a shortest side, a size of the shortest side is y microns, and the range of the radius of curvature of the at least one chamfered portion is from 5 microns to y/3 microns.

14. The light-emitting diode according to claim 7, wherein the protective layer comprises a silicon dioxide layer, a silicon nitride layer, or a silicon carbide layer.

15. A light-emitting diode, comprising:
a semiconductor stacked structure, comprising a first semiconductor layer, a light-emitting layer, and a second semiconductor layer, the light-emitting layer being located between the first semiconductor layer and the second semiconductor layer;
a first electrode, located on the first semiconductor layer;
a second electrode, located on the second semiconductor layer;
wherein when viewed from above the light-emitting diode toward the semiconductor stacked structure, the semiconductor stacked structure has at least one first type chamfered portion and at least one second type chamfered portion, a distance between the at least one first type chamfered portion and the first electrode is less than a distance between the at least one second type chamfered portion and the first electrode, a radius of curvature of the at least one first type chamfered portion is less than a radius of curvature of the at least one second type chamfered portion.

16. The light-emitting diode according to claim 15, characterized in that a range of the radius of curvature of the at least one first type chamfered portion is 5 microns to 50 microns.

17. The light-emitting diode according to claim 15, characterized in that a range of the radius of curvature of the at least one second type chamfered portion is 5 microns to 50 microns.

18. The light-emitting diode according to claim 15, characterized in that a ratio of the radius of curvature of the at least one first type chamfered portion to the radius of curvature of the at least one second type chamfered portion is 0.5 to 1.

19. A light-emitting diode, comprising:
a semiconductor stacked structure, comprising a first semiconductor layer, a light-emitting layer, and a second semiconductor layer, the light-emitting layer being located between the first semiconductor layer and the second semiconductor layer;
a first electrode, located on the first semiconductor layer;
a second electrode, located on the second semiconductor layer;
wherein the semiconductor stacked structure has a shortest side, a size of the shortest side is y microns, when viewed from above the light-emitting diode toward the semiconductor stacked structure, the semiconductor stacked structure has at least one chamfered portion, a range of a radius of curvature of the at least one chamfered portion is from 5 microns to y/3 microns.

20. A light-emitting device, comprising the light-emitting diode according to claim 1.
